(19) United States
(12) Patent Application Publication
(10) Pub. No.: US 2012/0329197 A1
(43) Pub. Date: Dec. 27, 2012

(54) METHOD OF BONDING AND FORMATION OF BACK SURFACE FIELD (BSF) FOR MULTI-JUNCTION III-V SOLAR CELLS

(75) Inventors: Stephen W. Bedell, Wappingers Falls, NY (US); Bahman Hekmatshoar-Tabari, Mount Kisco, NY (US); Devendra K. Sadana, Pleasantville, NY (US); Ghavam G. Shahidi, Round Ridge, NY (US); Davood Shahrjerdi, Ossining, NY (US)

(73) Assignee: INTERNATIONAL BUSINESS MACHINES CORPORATION, Armonk, NY (US)

(21) Appl. No.: 13/604,932

(22) Filed: Sep. 6, 2012

Related U.S. Application Data
(63) Continuation of application No. 13/080,934, filed on Apr. 6, 2011.

(51) Int. Cl. H01L 31/18

(52) U.S. Cl. 438/64; 438/68; 257/E31.11

(57) ABSTRACT

A photovoltaic device including at least one top cell that include at least one III-V semiconductor material; a bottom cell of a germanium containing material having a thickness of 10 microns or less; and a back surface field (BSF) region provided by a eutectic alloy layer of aluminum and germanium on the back surface of the bottom cell of that is opposite the interface between the bottom cell and at least one of the top cells. The eutectic alloy of aluminum and germanium bonds the bottom cell of the germanium-containing material to a supporting substrate.

### CROSS REFERENCE TO RELATED APPLICATION

This application is a continuation of U.S. patent application Ser. No. 13/080,934, filed Apr. 6, 2011, the entire content and disclosure of which is incorporated herein by reference.

The present disclosure relates to photovoltaic devices, and more particularly to photovoltaic devices such as, for example, solar cells.

A photovoltaic device is a device that converts the energy of incident photons to electromotive force (e.m.f.). Typical photovoltaic devices include solar cells, which are configured to convert the energy in the electromagnetic radiation from the Sun to electric energy. Multi-junction solar cells comprising compound semiconductors may be employed for power generation in space due to their high efficiency and radiation stability. Multi-junction solar cells are mainly fabricated on germanium (Ge) substrates due to the inherently strong (IR) absorption property of germanium (Ge). Germanium (Ge) also includes a crystal structure that can be lattice matched to III-V materials, which allows for integration of III-V sub cells on a germanium (Ge) substrate. The germanium (Ge) substrate may constitute nearly 50% to 70% of the final cost of the finished solar cell.

### BRIEF SUMMARY

In one embodiment, a photovoltaic device is provided that includes a eutectic alloy of aluminum germanium that provides a back surface field (BSF) region and bonds a germanium containing cell to a support substrate. In one embodiment, the photovoltaic device includes at least one top cell of at least one III-V semiconductor material that is present in direct contact with a bottom cell of a germanium containing material. The bottom cell of the germanium containing material has a thickness of 30 microns or less. The back surface of the bottom cell of the germanium containing material that is opposite the interface between the bottom cell and the at least one bottom cell includes a back surface field (BSF) region composed of a eutectic alloy of aluminum and germanium. The eutectic alloy of aluminum and germanium bonds the second cell of the germanium containing material to a supporting substrate.

In another aspect, a method of forming a photovoltaic device is provided, in which the photovoltaic device includes a eutectic alloy layer comprised of aluminum and germanium that provides a back surface field (BSF) region and bonds a germanium containing cell to a support substrate. In one embodiment, the method includes forming at least one top cell comprised of at least one III-V semiconductor material on a bottom cell comprised of a germanium containing material. The germanium containing material may be provided as a substrate having a first thickness. The bottom cell of germanium containing material may then be cleaved. A transferred portion of the germanium containing material having a second thickness that is less than the first thickness remains connected to the at least one top cell. A support substrate is then bonded to the cleaved surface of the germanium containing material by a eutectic alloy layer of aluminum and germanium. The eutectic alloy layer of aluminum and germanium passivates the cleaved surface of the germanium containing material.

In one example, the eutectic alloy layer is provided by directly depositing substantially aluminum, i.e., aluminum not containing germanium, onto a germanium surface followed by thermal annealing, or the eutectic alloy layer is provided by depositing an aluminum germanium alloy containing 25 atomic % to 50 atomic % germanium followed by annealing to provide eutectic bonding.

In another embodiment, a photovoltaic device is provided that includes a localized back surface field (LBSF) region provided by a eutectic alloy of aluminum and germanium. In one embodiment, the photovoltaic device includes at least one top cell of at least one III-V semiconductor material, and a bottom cell of germanium-containing material. The bottom cell of germanium containing material has a thickness of 30 microns or less. A localized back surface field (BSF) region comprised of a eutectic alloy region of aluminum and germanium is present extending into the bottom cell of the germanium containing material. A passivation layer is in direct contact with a back surface of the bottom cell comprised of the germanium containing material. The passivation layer includes aluminum containing plugs extending through the passivation layer into contact with the portion of the bottom cell of the germanium containing material that contains the localized back surface field (BSF) region. A support substrate is bonded to the passivation layer.

In another aspect, a method of forming a photovoltaic device is provided, in which the photovoltaic device includes a localized back surface field (BSF) region and bonds a germanium containing cell to a support substrate. In one embodiment, the method includes forming at least one top cell comprised of at least one III-V semiconductor material on a bottom cell comprised of a germanium containing material. The germanium containing material may be provided as a substrate having a first thickness. The bottom cell of germanium containing material is then cleaved. The transferred portion of the germanium containing material having a second thickness that is less than the first thickness remains connected to the at least one top cell of III-V semiconductor materials. A passivation layer comprised of silicon germanium is then deposited on the back surface of the bottom cell of the germanium containing material that is opposite the interface between the bottom cell and the at least one top cell. At least one opening is formed through the passivation layer. A support substrate is then engaged to the passivation layer by an aluminum containing bonding material, wherein the aluminum containing bonding material fills the opening through the passivation layer and diffuses into the back surface of the bottom cell of the germanium containing material to provide a localized back surface field (BSF) region.

### BRIEF DESCRIPTION OF THE DRAWINGS

The following detailed description, given by way of example and not intended to limit the disclosure solely thereto, will best be appreciated in conjunction with the accompanying drawings, wherein like reference numerals denote like elements and parts, in which:

FIG. 1A is a side cross-sectional view of a photovoltaic cell that includes a back surface field (BSF) region composed of a eutectic alloy of aluminum and germanium, in accordance with one embodiment of the present disclosure.

FIG. 1B is a side cross-sectional view of one embodiment of a top cell of III-V semiconductor materials, in accordance with one embodiment of the present disclosure.

FIG. 2 is a side cross-sectional view depicting one embodiment of a method of forming a photovoltaic device that includes forming at least one top cell including at least one III-V semiconductor material on a bottom cell of a germanium containing material, in accordance with one embodiment of the present disclosure.

FIG. 3 is a side cross-sectional view depicting cleaving the bottom cell of germanium containing material, wherein a transferred portion of germanium containing material remains connected to the top cell, in accordance with one embodiment of the present disclosure.

FIG. 4 is a side cross-sectional view depicting bonding a support substrate to a cleaved surface of the germanium containing material of the bottom cell with a eutectic alloy layer of aluminum and germanium, wherein the eutectic alloy layer of aluminum and germanium passivates the cleaved surface of germanium containing material, in accordance with one embodiment of the present disclosure.

FIG. 5 is a side cross-sectional view of one embodiment of a photovoltaic cell is that includes a localized back surface field (LBSF) region provided by a eutectic alloy region of aluminum and germanium, in accordance with the present disclosure.

FIG. 6 is a side cross-sectional view depicting forming a passivation layer comprised of silicon germanium on the cleaved back surface of a bottom cell of germanium containing material that is opposite the interface between the bottom cell and at least one top cell of at least one III-V semiconductor material, in accordance with one embodiment of the present disclosure.

FIG. 7 is a side cross-sectional view depicting forming at least one opening through the passivation layer to expose at least a portion of the back surface of the bottom cell of germanium containing material, in accordance with one embodiment of the present disclosure.

FIG. 8 is a side cross-sectional view depicting engaging a support substrate to the passivation layer with an aluminum containing bonding material, wherein at least a portion of the aluminum containing bonding material fills the opening through the passivation layer and diffuses into the back surface of the bottom cell of germanium-containing material to provide a localized back surface field (BSF) region, in accordance with one embodiment of the present disclosure.

### DETAILED DESCRIPTION

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on ” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

In one embodiment, the present disclosure provides a photovoltaic device, such as a solar cell, and a method of forming the same, that allows for simultaneous formation of the back surface field (BSF) in a germanium (Ge) substrate and bonding of the solar cell, such as a multi-junction III-V solar cell, onto a support substrate. As used herein, a “photovoltaic device” is a device, such as a solar cell, that produces free electrons and/or vacancies, i.e., holes, when exposed to radiation, such as light, and results in the production of an electric current. The photovoltaic device typically includes layers of p-type conductivity and n-type conductivity that share an interface to provide a heterojunction. In a single band gap solar cell, efficiency may be limited due to the inability to efficiently convert the broad range of energy that photons possess in the solar spectrum. Photons below the band gap of the cell material are lost, as they either pass through the cell or are converted to only heat within the material. Energy in the photons above the band gap energy is also lost, since only the energy necessary to generate the hole-electron pair is utilized, and the remaining energy is converted into heat.

Multi-junction photovoltaic cells, i.e., multi-junction solar cells, may include multiple films, i.e., layers, of semiconductor materials, in which each composition of semiconductor material will have a characteristic band gap energy. The semiconductor materials having the different band gap can be selected to cause the solar cell to absorb light most efficiently at specified color, or more precisely, to absorb electromagnetic radiation over a portion of the spectrum. These layers allow the cell to capture more of the solar spectrum and convert it into electricity. In some embodiments, to optimize the respective band gaps of the various junctions, each layer of semiconductor material in the solar cell should be lattice matched to the adjacent layers of the solar cell. For example, each layer of semiconductor material may be optically in series, with the highest band gap material at the top (top portion of the solar cell being the portion of the solar cell that the light enters first). The first junction receives all of the spectrum. Photons above the band gap of the first junction are absorbed in the first semiconductor layer of the solar cell. Photons below the band gap of the first layer pass through to the lower semiconductor layers to be absorbed there.

In some embodiments of a multi-junction solar cell device the top cells of the device are provided by III-V semiconductor materials, and the bottom cell of the device is provided by a germanium (Ge) containing substrate. As indicated above, the germanium (Ge) containing substrate constitues a substantial portion of the cost of the solar cell. In order to reduce the costs associated with germanium (Ge) containing substrates, the germanium (Ge) containing substrate may be processed using layer transfer techniques, such as cleavage of the germanium (Ge) containing substrate. Typically, the layer transfer techniques allow for the solar cell device to be physically seperated from the host substrate, e.g., germanium (Ge) containing host substrate, and transferred to a more economical handle substrate (also referred to as a “support substrate”). Layer transfer techniques allow for multiple applications of the germanium (Ge) containing host substrate. For example, following cleavage of the germanium (Ge) containing substrate, the cleaved transferred portion remains connected to the III-V semiconductor top cells, and the seperated portion of the germanium (Ge) containing substrate may then be employed in the formation of a second multi-junction III-V solar cell.

It has been discovered that the cleavage of the germanium (Ge) containing substrate may result in the formation of dangling bonds at the cleaved surface of the transferred portion of the germanium (Ge) containing substrate. The dangling bonds may disadvantagesly trap electron and hole charge carriers, therefore reducing the electric current produced by the solar cell. In some embodiments, in order for the transferred portion of the germanium (Ge) containing substrate to be current matched with the top cells of the solar cell that are composed of III-V semiconductor materials, the transferred portion of the germanium (Ge) containing substrate should be at least one micron thick, e.g., greater than 5 microns. Further, the thickness of the transferred portion of the germanium (Ge) containing substrate is typically selected to be less 10 microns so that the solar cell containing the transferred portion of the germanium (Ge) containing substrate can be economically manufactured. However, when the transferred portion of the germanium (Ge) containing substrate has a thickness of 10 microns or less, e.g., a thickness ranging from 5 microns to 10 microns, a substantial degradation of the conversion efficiency of the solar cell has been measured, which results from the loss of electron and hole charge carriers that are trapped by the dangling bonds at the cleaved surface of the transferred portion of the germanium (Ge) containing substrate. The solar cell performance is determined by the “effective” minority carrier lifetime, which depends on the minority carrier lifetime in the bulk as well as the surface recombination velocity. The thinner the absorbing layer, the stronger the effect of the surface recombination velocity will be on the effective minority carrier lifetime. The loss of electron and hole carriers that are trapped by the dangling bonds at the cleaved surface of the transferred portion of the (Ge) containing substrate results in a reduction in the current density and the open circuit voltage of the bottom cell of the solar cell that contains the transferred portion of the germanium (Ge) containing substrate.

In one embodiment, the present disclosure reduces the recombination of minority carriers, i.e., electron and/or hole charge carriers, by providing a back surface field (BSF) region. The introduction of the back surface field (BSF) region of the present disclosure may increase the short circuit current density and the open circuit voltage of the solar cell. A “back surface field (BSF)” is a doped region having a higher dopant concentration than the transferred portion of the germanium (Ge) containing substrate at the rear surface of the solar cell. The interface between the highly doped back surface field (BSF) region and the transferred portion of the germanium (Ge) containing substrate having a lower dopant concentration than the back surface field (BSF) region behaves like a p-n junction, and an electric field forms at the interface which introduces a barrier to minority carrier flow to the rear surface. The minority carrier concentration is thus maintained at higher levels in the transferred portion of the germanium (Ge) containing substrate and the back surface field (BSF) region has a net effect of passivating the rear surface of the solar cell.

In some embodiments, the methods and structures disclosed herein provide for simultaneously introducing the back surface field (BSF) region to the transferred portion of the germanium (Ge) containing substrate, and bonding of the multi-junction III-V solar cell that is formed on the transferred portion of the germanium (Ge) containing substrate to a support substrate. In one embodiment, the back surface field (BSF) region is provided by a germanium-aluminum alloy that has a eutectic temperature suitable for Al—Ge eutectic bonding. The “eutectic temperature” is the lowest melting point of an alloy or solution of two or more materials, e.g., aluminum (Al) and germanium (Ge). As used herein, “eutectic bonding” means a bond formed by heating two or more materials in a joint such that the materials diffuse together to form an alloy composition, e.g., Al—Ge, that melts at a lower temperature that the base materials, e.g., Al and Ge. A “eutectic alloy” is an alloy of at least two materials, i.e., alloy constituents, in which the alloyed material melts at a lower temperature than the each of the individual alloy constituents.

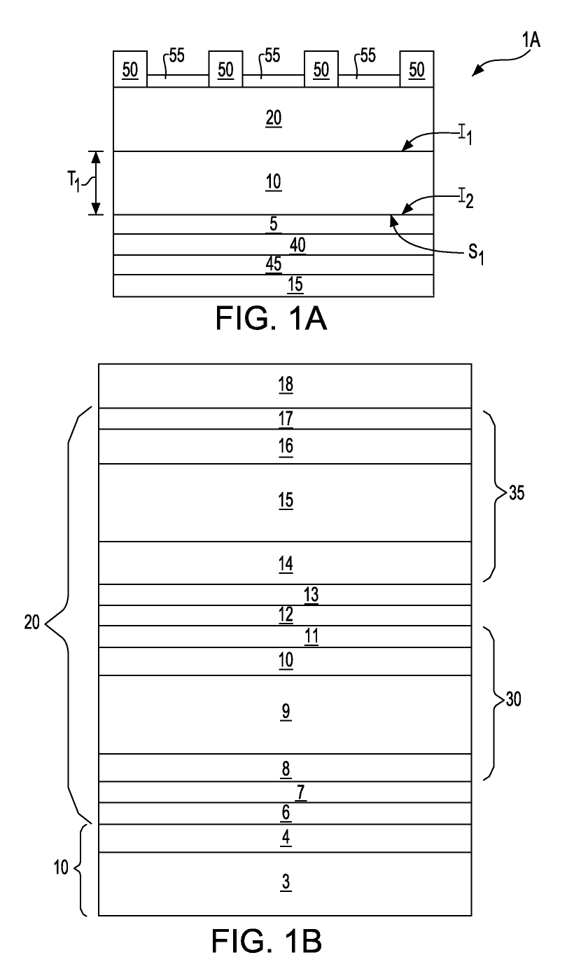

FIG. 1A depicts one embodiment of a photovoltaic cell 1A, such as a multi-junction III-V photovoltaic cell, that includes a eutectic alloy layer 5 of aluminum and germanium that provides a back surface field (BSF) region and bonds a germanium containing cell 10 (hereafter referred to as a bottom cell of germanium-containing material) to a support substrate 15. In one embodiment, the photovoltaic cell 1A includes at least one top cell 20 comprised of at least one III-V semiconductor material that is present in direct contact with a bottom cell 10 that is comprised of a germanium containing material. The bottom cell 10 of the germanium containing material has a thickness of 10 microns or less. The back surface of the bottom cell 10 of the germanium containing material that is opposite the interface between the bottom cell 10 and the at least one top cell 20 includes a back surface field (BSF) region comprised of a eutectic alloy layer 15 of aluminum and germanium. The eutectic alloy layer 15 of aluminum and germanium bonds the bottom cell 10 of the germanium containing material to the support substrate 15.

The at least one top cell 20 is composed of any number of layers of any number of III-V semiconductor materials. A “III-V semiconductor material” is an alloy composed of elements from group III and group V of the periodic table of elements. In one embodiment, the at least one top cell 20 is comprised of at least one III-V semiconductor material selected from the group consisting of aluminum antimonide (AlSb), aluminum arsenide (AlAs), aluminum nitride (AlN), aluminum phosphide (AlP), gallium arsenide (GaAs), gallium phosphide (GaP), indium antimonide (InSb), indium arsenic (InAs), indium nitride (InN), indium phosphide (InP), aluminum gallium arsenide (AlGaAs), indium gallium phosphide (InGaP), aluminum indium arsenic (AlInAs), aluminum indium antimonide (AlInSb), gallium arsenide nitride (GaAsN), gallium arsenide antimonide (GaAsSb), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), indium arsenide antimonide phosphide (InArSbP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide aluminum antimonide (GaInNAsSb), gallium indium arsenide antimonide phosphide (GaInAsSbP), and combinations thereof.

Each of the III-V semiconductor materials that provide the at least one top cell 20 may have a single crystal, multi-crystal or polycrystalline crystal structure. The term “single crystal crystalline structure” denotes a crystalline solid, in which the crystal lattice of the entire sample is substantially continuous and substantially unbroken to the edges of the sample, with substantially no grain boundaries. In another embodiment, the crystalline semiconductor material of the absorption layer 10 is of a polycrystalline structure. Contrary to a single crystal crystalline structure, a polycrystalline or multi-crystalline structure is a form of semiconductor material made up of randomly oriented crystallites and containing large-angle grain boundaries, twin boundaries or both. Each of the III-V semiconductor materials may be epitaxial.

To provide a junction with each of the cells in the at least one top cell 20 and to provide a junction with the bottom cell 10, the III-V semiconductor materials may be doped to a p-type or n-type conductivity. The effect of the dopant atom, i.e., whether it is a p-type or n-type dopant, depends occupied by the site occupied by the dopant atom on the lattice of the base material. In a III-V semiconductor, atoms from group II act as acceptors, i.e., p-type, when occupying the site of a group III atom, while atoms in group VI act as donors, i.e., n-type, when they replace atoms from group V. Dopant atoms from group IV, such a silicon (Si), have the property that they can act as acceptors or donor depending on whether they occupy the site of group III or group V atoms respectively. Such impurities are known as amphoteric impurities.

Each of the absorbing layers in the at least one top cell 20 may have a thickness ranging from 100 nm to 6,000 nm. In another embodiment, each of the layers in the at least one top cell 20 may have a thickness ranging from 500 nm to 4,000 nm.

In some embodiments, the at least one top cell 20 comprised of at least one III-V semiconductor material may include multi-layers of indium gallium phosphide (InGaP), indium gallium arsenide (InGaAs), indium phosphide (InP), gallium antimony (GaSb) and gallium arsenide (GaAs). Multi-junction photovoltaic cells may include multiple films, i.e., layers, of semiconductor materials, in which each composition of semiconductor material will have a characteristic band gap energy. Although, FIG. 1 only depicts a single layer for the at least one top cell 20, it is noted that at least one top cell 20 may be composed of any number of material layers having any number of material compositions. By adjusting the compositions of the III-V semiconductor materials of the top cell 20, a range of bandgap energies can be achieved. As a further consideration, in some embodiments, to produce the optimum optical transparency and maintain the greatest current conductivity between the top and bottom cells of the photovoltaic device 1A, it can be advantageous that each of the material layers in the at least one top cell 20 and the bottom cell 10 have similar crystal or lattice structures. In some embodiments, the composition of the material layers within the at least one top cell 20 are selected to provide material layers having a lattice structure that substantially matches the lattice structure of the surrounding material layers.

In one embodiment, the number of material layers and the compositions of the material layers within the at least one top cell 20 is selected to form a triple junction with the bottom cell 10. One example, of a triple junction cell photovoltaic device 1A may include indium gallium phosphide (InGaP), gallium arsenide (GaAs) or indium gallium arsenide (InGaAs) and germanium (Ge), which may be formed on a substrate composed of germanium (Ge).

FIG. 1B depicts one embodiment of a triple junction photovoltaic device 1B that is formed by combining the at least one top cell 20 of at least one III-V semiconductor material and the bottom cell 10 of germanium (Ge) containing material. In this example, the at least one at least one top cell 20 that is comprised of the at least one III-V semiconductor material provides two cells of the photovoltaic device, i.e., top cell 35 and middle cell 30, and the lowest cell of the photovoltaic device is provided by the bottom cell 10 of germanium containing material.

In one embodiment, a bottom tunnel junction is present between the bottom cell 10 and the middle cell 30. In one example, the bottom tunnel junction includes a lower layer 6 that is composed of Te:GaAs that is in direct contact with the bottom cell 10, and an upper layer 7 that is composed of C:Al₃Ga₇As that is in direct contact with the middle cell 30. In one embodiment, the middle cell 30 includes a back surface field layer 8 that is composed of Zn:In_{0.5}Ga_{0.5}P, and is in direct contact with the upper layer 7 of the bottom tunnel junction. A base layer 9 may be present atop the back surface field layer 8, wherein the base layer 9 may be composed of Zn:In_{0.5}Ga_{0.99}As. The middle cell 30 may also include an emitter layer 10 that is composed of Si:In_{0.1}Ga_{0.99}As. In one embodiment, the middle cell 30 further includes a middle cell window layer 11 that is present atop the emitter layer 10, and may be composed of Si:In_{0.1}Ga_{0.5}P.

In one embodiment, a top tunnel junction is present between the middle cell 30 and the top cell 35. In one example, the top tunnel junction includes a lower layer 12 that is composed of Te:GaAs that is in direct contact with the middle cell 30, and an upper layer 12 that is composed of C:Al₃Ga₇As that is in direct contact with the top cell 35. In one embodiment, the top cell 35 includes a back surface field layer 14 that is composed of Zn:In_{0.5}Ga_{0.2}Al_{0.3}P, and is in direct contact with the upper layer 13 of the top tunnel junction. A base layer 15 may be present atop the back surface field layer 14, wherein the base layer 15 may be composed of Zn:In_{0.5}Ga_{0.5}P. The top cell 35 may also include an emitter layer 16 that is composed of Si:In_{0.5}Ga_{0.5}P. In one embodiment, the top cell 35 further includes a top cell window layer 17 that is present atop the emitter layer 16, which may be composed of Si:In_{0.5}Al_{0.5}P. A contact 18 composed of Si:In_{0.01} Ga_{0.99}As may be present atop the top cell window layer 17.

Still referring to FIG. 1B, in one embodiment, the bottom cell 10 may include a base layer 3 of a p-type germanium containing substrate having a (100) orientation, and an emitter 4 composed of n-type germanium. The emitter 4 may include phosphorus dopant. It is noted that the above description of the at least one top cell 20 that is comprised of at least one III-V semiconductor material is provided for illustrative purposes only, and is not intended to limit the present disclosure, as other combinations of III-V semiconductor materials have also been contemplated, and are within the scope of the present disclosure.

Referring to FIG. 1A, the bottom cell 10 of germanium containing material may have a thickness T1 of 10 microns or less. In one embodiment, the thickness of the bottom cell 10 of germanium-containing material may range from 1 micron to 8 microns. In another embodiment, the thickness T1 of the bottom cell 10 of germanium containing material may range from 0.5 microns to 5 microns. The bottom cell 10 that is comprised of the germanium containing material may have a single crystal, multi-crystal or polycrystalline crystal structure.

The germanium containing material that provides bottom cell 10 may be substantially pure germanium (Ge) that is doped to a p-type conductivity. By substantially pure it is meant that the bottom cell 10 may be composed of a base material that is 99% germanium or greater, e.g., 100% germanium. The term substantially pure allows for the incorporation of incidental impurities that may be introduced to the base material during the formation process. The germanium containing base material that provides the bottom cell 10 may be doped to provide the conductivity type of the bottom cell 10. As used herein, the term “conductivity type” denotes a semiconductor material being p-type or n-type.

As used herein, “p-type” refers to the addition of impurities to an intrinsic semiconductor that creates deficiencies of valence electrons. In a bottom cell 10 composed of a germanium containing material, examples of p-type dopants, i.e., impurities, include but are not limited to boron, aluminum, gallium and indium. In one embodiment, in which the germanium-containing material that provides the bottom cell 10 has a p-type conductivity, the p-type dopant is present in a concentration ranging from 1×10¹⁴ atoms/cm³ to 1×10²⁰ atoms/cm³. In one embodiment, in which the germanium-containing material that provides the bottom cell 10 has a p-type conductivity, the p-type dopant is present in a concentration ranging from 1×10¹⁴ atoms/cm³ to 1×10¹⁸ atoms/cm³. In yet another embodiment, in which the germanium-containing material that provides the bottom cell 10 has a p-type conductivity, the p-type dopant is present in a concentration ranging from 1×10¹⁵ atoms/cm³ to 1×10¹⁹ atoms/cm³.

As used herein, “n-type” refers to the addition of impurities that contributes free electrons to an intrinsic semiconductor. In a bottom cell 10 comprised of a germanium containing material, examples of n-type dopants, i.e., impurities, include but are not limited to, antimony, arsenic and phosphorous. In one embodiment, in which the germanium containing material that provides bottom cell 10 has an n-type conductivity, the n-type dopant is present in a concentration ranging from 1×10¹⁴ atoms/cm³ to 1×10²⁰ atoms/cm³. In another embodiment, in which the germanium containing material that provides bottom cell 10 has an n-type conductivity, the n-type dopant is present in a concentration ranging from 1×10¹⁵ atoms/cm³ to 1×10¹⁹ atoms/cm³.

In some examples, an upper portion of the germanium containing material that provides the bottom cell 10 has a first conductivity, e.g., an n-type conductivity, and a lower portion of the germanium-containing material that provides the bottom cell 10 has a second opposing conductivity, e.g., a p-type conductivity. For example, referring to FIG. 1B, in one embodiment of the present disclosure in which a triple junction photovoltaic device is provided, the bottom cell 25 of the triple junction device that is provided by the bottom cell 10 of germanium containing material may include an n-type emitter portion 4 that is formed on a substrate 3 of p-type germanium (“Ge”). The substrate 3 of the p-type germanium may serve as a base layer of the bottom cell 25 of the triple junction photovoltaic device. The concentration of the n-type dopant in the n-type emitter portion 4 of the bottom cell 10 that is composed of the germanium containing material may range from 1×10¹⁸ atoms/cm³ to 5×10²⁰ atoms/cm³. The concentration of the p-type dopant in the p-type germanium containing substrate 3 that provides the base layer may range from 1×10¹⁴ atoms/cm³ to 1×10¹⁸ atoms/cm³.

Referring to FIG. 1A, in one embodiment, a back surface field (BSF) region comprised of a eutectic alloy layer 5 of aluminum and germanium is present in direct contact with the back surface Si of the bottom cell 10 of the germanium containing material. The back surface S1 of the bottom cell 10 of germanium containing material is opposite the interface I1 between the bottom cell 10 of germanium containing material and the at least one top cell 20 of at least one III-V semiconductor material. In this embodiment, the eutectic alloy layer 5 extends across the entire width of the back surface of the bottom cell 10, and provides a back surface field (BSF) region that extends across the entire width of the bottom cell 10 of the germanium containing material.

As used herein, a “back surface field (BSF) region” is a higher doped region at the back surface S1 of the bottom cell 10 of germanium containing material. The back surface field (BSF) region can serve to passivate the back surface of the bottom cell 10, and reduce electron-hole recombination. The interface 12 between the high and low doped regions, i.e., interface between the back surface of the bottom cell 10 and the upper surface of the eutectic alloy layer 5, produces an electric field that functions as a barrier to minority carrier flow to the back surface S1 of the bottom cell 10 of germanium containing material. For example, an electric field that is suitable for obstructing recombination of minority carriers, e.g., electrons, may be produced by an interface 12 between a highly doped p-type back surface field (BSF) region, e.g., having a p-type dopant concentration ranging from 1×10¹⁷ atoms/cm³ to 5×10²⁰ atom/cm³, and a p-type bottom cell 10, e.g., having a p-type dopant concentration ranging from 1×10¹⁴ atoms/cm³ to 1×10¹⁸ atom/cm³.

In one embodiment, the eutectic alloy layer 5 of aluminum and germanium includes 0.01 atomic % to 20 atomic % aluminum. In another embodiment, the eutectic alloy layer 5 of aluminum and germanium includes 0.01 atomic % to 10 atomic % aluminum. In one embodiment, the eutectic alloy layer 5 of aluminum and germanium includes 0.1 atomic % to 1 atomic % germanium.

Referring to FIG. 1A and 1B, in one embodiment, the eutectic alloy layer 5 of aluminum and germanium is doped to the same conductivity type as the bottom cell 10 of germanium containing material, e.g., same conductivity as the base portion 3 of the bottom cell 10, in which the dopant concentration that provides the conductivity type of eutectic alloy layer 5 of aluminum and germanium is greater than the dopant concentration that provides the conductivity type of the bottom cell 10 of germanium containing material, e.g., base portion 3 of the bottom cell 10 of germanium containing material. For example, when the bottom cell 10 of the germanium containing material, e.g., base portion 3 of the bottom cell, is doped to a p-type conductivity, the eutectic alloy layer 5 of aluminum and germanium is doped to a p-type conductivity.

In one embodiment, the total dopant concentration that provides the conductivity type of the eutectic alloy layer 5 of aluminum and germanium ranges from 1×10¹⁷ atoms/cm³ to 2×10²⁰ atom/cm³. In another embodiment, the total dopant concentration that provides the conductivity type of the eutectic alloy layer 5 of aluminum and germanium ranges from 1×10¹⁷ atoms/cm³ to 2×10²⁰ atom/cm³. The total concentration of dopant that dictates the conductivity type of the eutectic alloy layer 5 of aluminum and germanium includes the concentration of aluminum atoms, as well as the concentration of the p-type dopant from the bottom cell 10 of germanium containing material that is present in the eutectic alloy layer 5 of aluminum and germanium. However, the dopant concentration of the bottom cell is practically less than that of the back surface field. For example, when the eutectic alloy layer 5 is doped a p-type conductivity, the total concentration of p-type dopant in the back surface field (BSF) region comprises p-type dopant from the bottom cell 10 of germanium containing material in a concentration ranging from 1×10¹⁴ atoms/cm³ to 2×10¹⁸ atoms/cm³, and a concentration of aluminum atoms ranging from 1×10¹⁷ atoms/cm³ to 2×10²⁰ atoms/cm³.

The eutectic alloy layer 5 of aluminum and germanium may have a thickness ranging from 50 nm to 5,000 nm. In another embodiment, the eutectic alloy layer 5 of aluminum and germanium may have a thickness ranging from 500 nm to 3000 nm.

Still referring to FIG. 1A, the eutectic alloy layer 5 of aluminum and germanium bonds the bottom cell 10 of germanium-containing material to a supporting substrate 15. In some embodiments, an optional aluminum containing layer 40, and an optional transparent conductive material layer 45, may be present between the eutectic alloy layer 5 of aluminum and germanium and the support substrate 15. In one embodiment, the aluminum-containing layer is composed of greater than 90 wt. % aluminum, e.g., greater than 95% aluminum. In another embodiment, the aluminum containing layer 40 is composed of greater than 99% aluminum. The aluminum content of the aluminum containing layer 40 may be approximately 100% aluminum with incidental impurities. Incidental impurities are impurities that are inadvertently introduced to the aluminum containing layer 40 during the processes sequences for forming the aluminum containing layer 40. The aluminum containing layer 40 may have a thickness ranging from ranging from 50 nm to 20,000 nm. In another embodiment, the aluminum containing layer 40 may have a thickness ranging from 100 nm to 10,000 nm.

The transparent conductive material layer 45 may be present in direct contact with and between the aluminum containing layer 40 and the support substrate 15. Throughout this disclosure an element is “transparent” if the element is transparent in the visible electromagnetic spectral range having a wavelength from 400 nm to 800 nm. The transparent conductive material layer 45 may include a conductive material that is transparent in the range of electromagnetic radiation at which photogeneration of electrons and holes occur within the solar cell structure. In one embodiment, the transparent conductive material layer 45 can include a transparent conductive oxide such as, but not limited to, a fluorine-doped tin oxide (SnO₂:F), an aluminum-doped zinc oxide (ZnO:Al), tin oxide (SnO) and indium tin oxide (InSnO₂, or ITO for short). The thickness of the transparent conductive material layer 45 may vary depending on the type of transparent conductive material employed, as well as the technique that was used in forming the transparent conductive material. Typically, and in one embodiment, the thickness of the transparent conductive material layer 45 ranges from 10 nm to 3 microns. Other thicknesses, including those less than 10 nm and/or greater than 3 microns can also be employed. In some examples, a metal layer may be substituted with the transparent conductive material layer 45. The metal layer may be composed of aluminum, silver, copper, titanium, gold, nickel and combinations thereof.

The support substrate 15 can be formed from a mechanically-flexible material, such as a flexible polymer, or a rigid material, such as a glass. Examples of polymers that can be used to form a flexible support substrate 15 include polyethylene naphthalates (PEN), polyethylene terephthalates (PET), polyethyelenes, polypropylenes, polyamides, polymethylmethacrylate, polycarbonate, and/or polyurethanes. A flexible support substrate 15 may also be provided by a metal foil, such as an aluminum foil.

The thickness of support substrate 15 can vary as desired. Typically, the support substrate 15 thickness and type are selected to provide mechanical support sufficient to withstand the rigors of manufacturing, deployment, and use. In one embodiment, the support substrate 15 can have a thickness ranging from 6 μm to 5,000 μm. In another embodiment, the support substrate 15 can have a thickness ranging from 6 μm to about 50 μm. In another embodiment, the support substrate 15 has a thickness ranging from 50 μm to 5,000 μm. In yet another embodiment, the support substrate 15 has a thickness ranging from 100 μm to 1,000 μm.

Still referring to FIG. 1A, the front contact 50 of the photovoltaic device 1A may include a set of parallel narrow finger lines and wide collector lines deposited essentially at a right angle to the finger lines. The front contact 50 may be deposited with a screen printing technique or photolithography or some other techniques. In another embodiment, the front contact 50 is provided by the application of an etched or electroformed metal pattern. The metallic material used in forming the metal pattern for the front contact 50 may also be deposited using sputtering or plating. The thickness of the front contact 50 can range from 100 nm to 1 μm, although lesser and greater thicknesses can also be employed. In some embodiments, forming the front contact 50 may include applying an antireflection (ARC) coating 55. The antireflection coating (ARC) 55 may be composed of silicon nitride (SiNₓ) or silicon oxide (SiOₓ) grown by PECVD at temperatures as low as 200° C. In another example, the antireflective coating (ARC) 55 may be a dual layer structure composed of zinc-sulfide (ZnS) and magnesium fluoride (MgF₂). Other embodiments have been contemplated that do not include the above compositions for the antireflection coating (ARC) 55 and the front contact 50.

One embodiment of a method of forming the photovoltaic device 1A that is depicted in FIG. 1A is now described with reference to FIGS. 2-4. FIG. 2 depicts one embodiment of forming at least one top cell 20 including at least one III-V semiconductor material on a bottom cell 10 of a germanium containing material. The bottom cell 10 of the germanium containing material may be provided as a substrate having an original thickness T2 ranging from 1 μm to 50 μm. In another embodiment, the substrate that provides the bottom cell 10 of germanium containing material may have an original thickness T2 ranging from 1.5 μm to 20 μm.

In one embodiment, the substrate that provides the bottom cell 10 of germanium containing material may be formed using a single cystal (monocrystalline) method.

The substrate that provides the bottom cell 10 of germanium containing material may also include epitaxially formed layers of germanium. The terms “epitaxially formed”, “epitaxial growth” and/or “epitaxial deposition” means the growth of a semiconductor material on a deposition surface of a semiconductor material, in which the semiconductor material being grown has the same crystalline characteristics as the semiconductor material of the deposition surface. Therefore, in the embodiments in which the substrate that provides the bottom cell 10 of germanium has a single crystal crystalline structure, the epitaxially grown germanium layer also has a single crystal crystalline structure. Further, in the embodiments in which the substrate that provides the bottom cell 10 of germanium has a polycrystalline structure, a germanium layer that is epitaxially grown on the bottom cell 10 of germanium will also have a polycrystalline structure.

The dopant that determines the conductivity type of the substrate may be introduced during the method of forming the substrate that provides the bottom cell 10 of germanium, or the epitaxially formed germanium layers present on the substrate, via an in-situ doping process. In another embodiment, the dopant that determines the conductivity type of the bottom cell 10 of germanium may be introduced to the substrate of germanium, or the epitaxially formed layers of germanium, using ion implantation.

Still referring to FIG. 2, at least one top cell 20 including at least one III-V semiconductor material may then be formed on the bottom cell 10 of a germanium containing material. As noted above, any number of layers and compositions of III-V semiconductor materials may be included in the at least one top cell 20. The III-V semiconductor material may be formed atop the bottom cell 10 of germanium using an epitaxial growth process, such as chemical vapor deposition. CVD is a deposition process in which a deposited species is formed as a result of chemical reaction between gaseous reactants, wherein the solid product of the reaction is deposited on the surface on which a film, coating, or layer of the solid product is to be formed. Variations of CVD processes suitable include, but are not limited to, Atmospheric Pressure CVD (APCVD), Low Pressure CVD (LPCVD) and Plasma Enhanced CVD (PECVD), Metal-Organic CVD (MOCVD), molecular beam epitaxy (MBE) and combinations thereof.

The dopant that dictates the conductivity type of the III-V semiconductor materials that are included in the at least one top cell 20 may be introduced during the method of forming the III-V semiconductor materials via an in-situ doping process. The in-situ doping can be effected by adding a dopant gas including at least one p-type dopant or n-type dopant into the gas stream that includes the deposition precursors for the III-V semiconductor material. In another embodiment, the dopant that determines the conductivity type of the III-V semiconductor materials may be implanted using ion implantation.

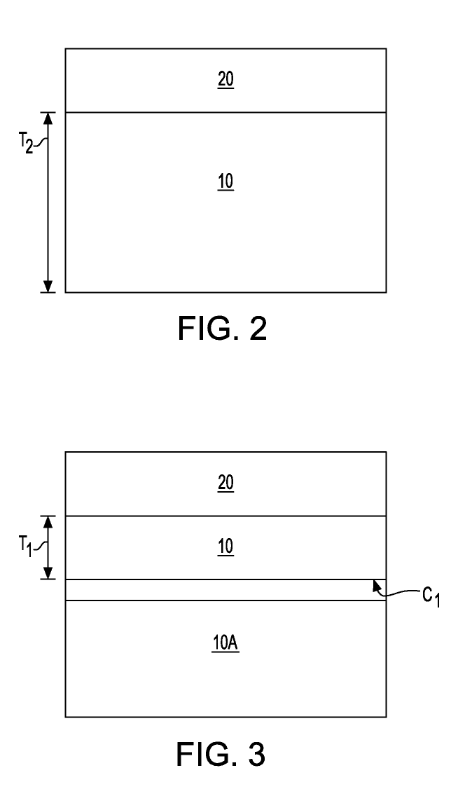

FIG. 3 depicts one embodiment of cleaving the bottom cell 10 of germanium containing material, wherein a transferred portion 10A of the germanium containing material remains connected to the top cell 20 of the III-V semiconductor materials. By “cleaving” it is meant that a transferred portion of the bottom cell 10 that is connected to the at least one top cell 20 of the III-V semiconductor materials is separated from a second portion 10A of the bottom cell that is not connected to the at least one top cell 20 of the III-V semiconductor materials, so that the transferred portion of the bottom cell 10 of the germanium containing material has a thickness T1 that is less than the original thickness T2 of the bottom cell 10. The cleaving of the bottom cell 10 of the germanium containing material may include smart cut layer transfer, spalling, mechanical separation or a combination thereof.

Smart cut layer transfer is a method that includes implanting hydrogen into the bottom cell 10 of germanium containing material having the original thickness T2, and then annealing the bottom cell 10 of germanium containing material to produce hydrogen bubbles. The bubbles formed within the bottom cell 10 of the germanium containing material cause a shear mechanism that removes the separated portion 10A of the bottom cell. The hydrogen may be implanted using ion implantation. In one example, annealing of the implanted hydrogen may occur at a temperature ranging from 400° C. to 600° C., such as 500° C. Another, shearing method, “smarter cut” includes a boron and hydrogen implant that causes sheer after being annealed at a temperature of approximately 180° C. It is noted that the present disclosure is not limited to boron and hydrogen, as other gas forming elements have been contemplated for a smart cut type process to cleave the bottom cell 10 of the germanium containing material.

Cleaving of the bottom cell 10 of the germanium containing material by controlled spalling may include applying a stress inducing material to the structure that includes the bottom cell 10 of germanium containing material, and the top cell 20 of the III-V semiconductor materials, wherein the stress inducing material causes a shear mechanism that removes the seperated portion of the bottom cell 10. The stress inducing material may be a metal, such as nickel (Ni), Ti, Cr, and alloys thereof. The stress inducing material may be in contact with at least one of the back side surface of the bottom cell 10, and the upper surface of the at least one top cell 20. Following cleaving the stress inducing material may be removed.

The separated portion 10A of the bottom cell may be utilized in the formation of another photovoltaic device, such as a multi-junction III-V photovoltaic device. In one embodiment, the thickness of the separated portion 10A of the bottom cell may be increased by epitaxially forming a germanium layer on the cleaved surface of the separated portion 10A of the bottom cell.

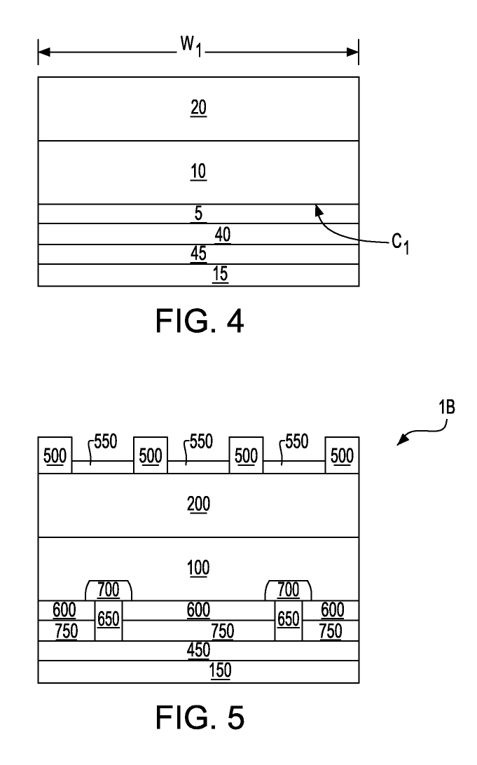

FIG. 4 depicts one embodiment of a support substrate 15 bonded to the cleaved surface of the germanium containing material with a eutectic alloy layer 5 of aluminum and germanium. In one embodiment, in addition to bonding the support substrate 15 to the bottom cell 10 of germanium containing material, the eutectic alloy layer 5 of aluminum and germanium provides a back surface field (BSF) region that extends across the entire width W1 of the photovoltaic device, and passivates the cleaved surface of the germanium containing material. By passivating the cleaved surface of the germanium containing material, the eutectic alloy layer 5 of the aluminum and germanium reduces or substantially eliminated the recombination of the minority charge carriers, i.e., electrons, at the back surface of the bottom cell 10 of germanium containing material.

In one embodiment, the bonding of the support substrate 15 to the cleaved surface C1 of the germanium containing material of the bottom cell 10 with the eutectic alloy layer 5 of aluminum and germanium may include the steps of: applying an aluminum containing metal layer 40 on at least one of the cleaved surface C1 of the germanium containing material of the bottom cell 10 and the support substrate 15; contacting the aluminum containing metal layer 14 between the cleaved surface C1 of the germanium containing material and the support substrate 15; and annealing at a temperature that is above the eutectic temperature of the eutectic alloy layer 15 of aluminum and germanium. In one embodiment, the eutectic temperature ranges from 420° C. to 750° C.

The aluminum-containing layer 40 may be comprised of greater than 70 wt. % aluminum, e.g., greater than 95% aluminum. In another embodiment, the aluminum containing layer 40 is comprised of greater than 99% aluminum. The aluminum content of the aluminum containing layer 40 may be approximately 100% aluminum with incidental impurities. Incidental impurities are impurities that are inadvertently introduced to the aluminum containing layer 40 during the processes sequences for forming the aluminum containing layer 40. The deposited thickness of the aluminum containing layer 40 before annealing to form the eutectic alloy layer 5 of aluminum and germanium may range from 5 nm to 20,000 nm. In another embodiment, the deposited thickness of the aluminum containing layer 40 may range from 50 nm to 10,000 nm.

The aluminum containing metal layer 40 may be deposited using a physical vapor deposition (PVD) method, such as sputtering or plating. As used herein, “sputtering” means a method for depositing a film of metallic material, in which a target of the desired material, i.e., source, is bombarded with particles, e.g., ions, which knock atoms from the target, where the dislodged target material deposits on a deposition surface, i.e., upper surface of the semiconductor substrate 5. Examples of sputtering apparatus that may be suitable for depositing the aluminum containing metal layer 40 include DC diode type systems, radio frequency (RF) sputtering, magnetron sputtering, and ionized metal plasma (IMP) sputtering.

In one embodiment, the aluminum containing metal layer 40 is deposited in direct contact with the cleaved surface C1 of the bottom cell 10 of germanium containing material. In this embodiment, following deposition of the aluminum containing metal layer 40 on the cleaved surface C1 of the bottom cell 10, a support substrate assembly is then brought into contact with the aluminum containing metal layer 40 and annealed. In the embodiment that is depicted in FIG. 4, the support substrate assembly includes an optional transparent conductive material layer 45 that is formed on a support substrate 15. The support substrate 15 has been described above with reference to FIG. 1A. In one embodiment, the transparent conductive material layer 45 can be composed of a fluorine-doped tin oxide (SnO₂:F), an aluminum-doped zinc oxide (ZnO:Al), tin oxide (SnO) and indium tin oxide (InSnO₂, or ITO for short). The transparent conductive material layer 45 is typically formed using a deposition process, such as CVD. Examples of CVD processes suitable for forming the transparent conductive material layer 45 include, but are not limited to, APCVD, LPCVD, PECVD, MOCVD and combinations thereof. As indicated above, a metal layer may be substituted for the transparent conductive material layer 45, which may be deposited using plating or sputtering.

In the embodiments, in which the transparent conductive material layer 45 are present on the support substrate 15, the transparent conductive material layer 45 is brought into direct contact with the aluminum containing metal layer 40, and is then annealed to form the eutectic alloy layer 5 of aluminum and germanium that bonds the bottom cell 10 of the germanium containing material to the support substrate assembly that includes the transparent conductive material layer 45 and the support substrate 15. In the embodiments, in which the transparent conductive material layer 45 is omitted, the support substrate 15 may be brought into direct contact with the aluminum containing metal layer 40 that has been deposited on the cleaved surface C1 of the bottom cell 10, and is then annealed to form the eutectic alloy layer 5 of aluminum and germanium that bonds the bottom cell 10 of germanium containing material to the support substrate 15.

In one embodiment, the aluminum containing metal layer 40 is deposited directly on the support substrate assembly. For example, in the embodiments in which the support substrate assembly includes an optional transparent conductive material layer 45 or metal layer that is formed on a support substrate 15, the aluminum containing metal layer 40 may be deposited in direct contact with the optional transparent conductive material layer 45 or metal layer that is formed on a support substrate 15. In another example, in which the optional transparent conductive material layer 45 or metal layer has been omitted, the aluminum containing metal layer 40 may be deposited in direct contact with the support substrate 15. Following the deposition of the aluminum containing metal layer 40 on the support substrate assembly, the aluminum containing metal layer 40 is contacted to the cleaved surface C1 of the bottom cell 10, and is then annealed to form the eutectic alloy layer 5 of aluminum and germanium that bonds the bottom cell 10 of the germanium containing material to the support substrate 15.

Thermal annealing of the aluminum containing metal layer 40 forms a bond between the aluminum containing metal layer 40 and the cleaved surface C1 of the bottom cell 10 of germanium containing material. During thermal annealing, aluminum atoms from the aluminum containing metal layer 40 diffuse into the bottom cell 10 of germanium containing material to form a eutectic alloy layer 5 of aluminum and germanium. The eutectic alloy layer 5 of germanium and aluminum extends across the entire width W1 of the back surface of the bottom cell 10 of the germanium containing material. In this embodiment, the eutectic alloy layer 5 of germanium and aluminum provides a back surface field (BSF) region that extends across the entire width W1 of the back surface of the bottom cell 10. In one embodiment, as the annealing temperature is increased the diffusion of aluminum into the bottom cell 10 of germanium containing material is increased.

Thermally annealing may be provided by laser annealing, flash annealing, rapid thermal annealing (RTA) and combinations thereof. The annealing of the aluminum containing metal layer 40 is typically conducted at a temperature that is greater than the eutectic temperature for a eutectic alloy of aluminum and germanium. Typically, the eutectic temperature of a eutectic alloy of aluminum and germanium ranges from 400° C. to 500° C. In another embodiment, the eutectic temperature of a eutectic alloy of aluminum and germanium ranges from 425° C. to 475° C. In one example, the eutectic temperature of a eutectic alloy of aluminum and germanium is 426° C.

Typically, aluminum atoms from the aluminum containing metal layer 40 diffuse to a distance of 50 nm to 40,000 nm into the bottom cell 10, as measured from the cleaved surface of the bottom cell 10. In another embodiment, the aluminum atoms from the aluminum containing metal layer 40 diffuse to a distance of 100 nm to 20,000 nm into the bottom cell 10, as measured from the cleaved surface of the bottom cell 10.

In some embodiments, the entire thickness of the aluminum containing metal layer 40 intermixes with germanium from the bottom cell 10 to provide a eutectic alloy layer 5 that is in direct contact with the back surface of bottom cell 10 and is in direct contact with the support substrate assembly. For example, the eutectic alloy layer 5 may be in direct contact with the optional transparent conductive material layer 45, or the eutectic alloy layer 5 is in direct contact with the support substrate 15 when the optional conductive material layer 45 is omitted.

Referring to FIG. 1A, the front contact 50 may then be formed in electrical communication with at least the at least one top cell 20 of at least one III-V semiconductor material.

FIG. 5 depicts another embodiment of a photovoltaic device 1B, such as a multi-junction III-V photovoltaic device, formed in accordance with the present disclosure. The photovoltaic device 1B that is depicted in FIG. 5 includes a passivation layer 600 in direct contact with a back surface of a bottom cell 100 of germanium containing material, wherein the passivation layer 600 includes aluminum containing plugs 650 extending therethrough, and a localized back surface field (BSF) region comprised of a eutectic alloy region 700 of aluminum and germanium. As used herein, the term “localized back surface (BSF) region” denotes a back surface field region that does not extend across the entire width of the back surface of the bottom cell 100 of germanium containing material.

The passivation layer 600 is a material layer that is formed on the back surface of the bottom cell 100 that reduces the concentration of dangling bonds at cleaved surface of the bottom cell 10 of germanium containing material. Similar to the bottom cell 10 that is described above with reference to FIGS. 1A-4, the bottom cell 100 that is depicted in FIG. 5 may be subjected to a cleaving step that results in the formation of dangling bonds. The dangling bonds disadvantageously result in recombination of the minority charge carriers, i.e., electrons and holes, at the back surface of the bottom cell 100. The passivation layer 600 is composed of a material that passivates the back surface of the bottom cell 100 by forming bonds with the dangling bonds, therefore reducing the density of dangling bonds at which the recombination of minority charge carriers may occur.

In one embodiment, the passivation layer 600 may be composed of silicon germanium (SiGe).

In the embodiments, in which the passivation layer 600 is composed of silicon germanium (SiGe), in which the germanium (Ge) content may be as great as 80%, by atomic weight %. In another embodiment, the germanium (Ge) content of the passivation layer 600 may range from 10% to 20%. The passivation layer 600 may be composed of a crystalline material, such as a material having a single crystal crystalline structure, amorphous, or polycrystalline crystal structure. The passivation layer 600 may have a thickness ranging from 3 nm to 10,000 nm. In another embodiment, the thickness of the passivation layer 600 may range from 5 nm to 300 nm.

At least one opening may be present through the passivation layer 600 to the cleaved surface of the bottom cell 100. Each opening may have a width ranging from 50 nm to 100 μm. In one embodiment, each of the openings through the passivation layer 600 has a width ranging from 500 nm to 80 μm. Each of the at least one opening may be separated from an adjacent opening of the at least one opening by a dimension ranging from 50 μm to 8,000 μm. In another embodiment, each of the at least one opening may be separated from an adjacent opening of the at least one opening by a dimension ranging from 200 μm to 4,000 μm.

The aluminum containing plugs 650 positioned in the openings through the passivation layer 600 may include greater than 70 wt. % aluminum, e.g., greater than 95% aluminum. In another embodiment, the aluminum containing plugs 650 are composed of greater than 99% aluminum. The aluminum content of the aluminum containing plugs 650 may be approximately 100% aluminum with incidental impurities. Incidental impurities are impurities that are inadvertently introduced to the aluminum containing plugs 650 during the processes sequences for forming the aluminum containing plugs 650.

Still referring to FIG. 5, in one embodiment, the eutectic alloy region 700 that provides the localized back surface field (BSF) region includes 0.01 atomic % to 20 atomic % aluminum. In another embodiment, the eutectic alloy region 700 of aluminum and germanium includes 0.1 atomic % to 1 atomic % aluminum.

In one embodiment, the total dopant concentration that provides the conductivity type of the eutectic alloy region 700 of aluminum and germanium ranges from 1×10¹⁷ atoms/cm³ to 2×10²⁰ atom/cm³. In another embodiment, the total dopant concentration that provides the conductivity type of the eutectic alloy region 700 of aluminum and germanium ranges from 1×10¹⁸ atoms/cm³ to 1×10²⁰ atom/cm³.

Each of the eutectic alloy regions 700 typically extend from the aluminum containing plugs 650 into the bottom cell 100 of germanium containing material. The eutectic alloy region 700 of aluminum and germanium may have a width ranging from 500 nm to 80 μm, and may extend into the bottom cell by a dimension ranging from 5 nm to 20,000 nm, as measured from the interface between the aluminum containing plugs 650 and the bottom cell 100. Each of the eutectic alloy regions 700 may be separated from an adjacent eutectic alloy region 700 by a dimension ranging from 50 μm to 8,000 μm. In another embodiment, each of eutectic alloy regions 700 may be separated from an adjacent eutectic alloy region 700 by a dimension ranging from 200 μm to 4,000 μm.

The photovoltaic device 1B that is depicted in FIG. 5 may further include a dielectric layer 750 in direct contact with the passivation layer 600, wherein the aluminum containing plugs 650 that are present in the passivation layer 600 also extend through the dielectric layer 750. The dielectric layer 750 may be comprised of an oxide, nitride or oxynitride material. In one example, in which the dielectric layer 750 is composed of an oxide, the dielectric layer 750 may be silicon oxide (SiO₂). In one example, in which the dielectric layer 750 is composed of a nitride, the dielectric layer 750 may be silicon nitride. The dielectric layer 750 may have a thickness ranging from 5 nm to 500 nm. In another embodiment, the thickness of the dielectric layer 750 may range from 10 nm to 300 nm.

An optional transparent conductive material layer 450 may be present in direct contact with the dielectric layer 750 and the support substrate 150. The transparent conductive material layer 450 that is depicted in FIG. 5 is similar to the transparent conductive material layer 45 that is depicted in FIG. 1A. Therefore, the description of the transparent conductive material layer 45 that is depicted in FIG. 1A is suitable for the transparent conductive material layer 450 that is depicted in FIG. 5.

The photovoltaic device 1B depicted in FIG. 5 includes at least one top cell 200 that is comprised of a III-V semiconductor material that is present atop a bottom cell 100 of germanium containing material. The bottom cell 10 of the germanium containing material has a thickness T1 of 10 microns or less. The at least one least one top cell 200 and the bottom cell 100 that are depicted in FIG. 5 are similar to the at least one top cell 20 and the bottom cell 100 that is described above with reference to FIG. 1A. Therefore, the description of the at least one top cell 20 and the bottom cell 10 that are depicted in FIG. 1A is suitable for the at least one least one top cell 200 and the bottom cell 100 that are depicted in FIG. 5.

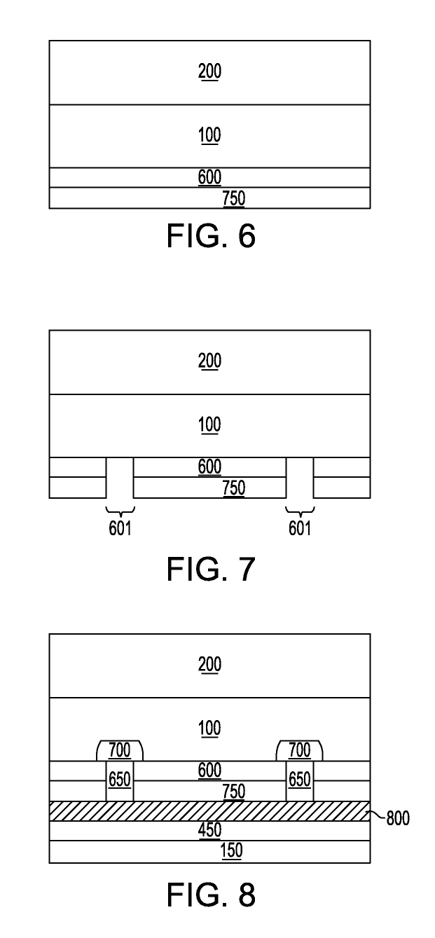

One embodiment of a method of forming the photovoltaic device 1B that is depicted in FIG. 5 is now described with reference to FIGS. 6-8. In one embodiment, the photovoltaic device 1B may be formed by a method that may begin with the steps of forming at least one top cell 200 comprised of at least one III-V semiconductor material on a bottom cell 100 comprised of a germanium containing material; and cleaving the bottom cell 100 so that a transferred portion of the germanium containing material remains connected to the top cell 200. The steps of forming the at least one top cell 200 of III-V semiconductor material on the bottom cell 100 of the germanium containing material; and cleaving the bottom cell of the germanium containing material have been described above with reference to FIGS. 2 and 3.

FIG. 6 depicts one embodiment of forming a passivation layer 600 comprised of silicon germanium on the cleaved back surface of a bottom cell 100 of the germanium-containing material that is opposite the interface between the bottom cell 100 and the at least one top cell 200 composed of at least one III-V semiconductor material. In one embodiment, the passivation layer 600 may be epitaxially formed on the cleaved back surface of the bottom cell 100 using an epitaxial growth process, such as chemical vapor deposition (CVD). Variations of CVD processes suitable for depositing the passivation layer 600 include, but are not limited to, Atmospheric Pressure CVD (APCVD), Low Pressure CVD (LPCVD) and Plasma Enhanced CVD (PECVD), Metal-Organic CVD (MOCVD) and combinations thereof. The passivation layer 600 may be epitaxially grown via plasma enhanced chemical vapor deposition (PECVD) from a mixture of silane (SiH₄), germane (GeH₄), hydrogen (H₂) and dopant gasses.

FIG. 6 further depicts one embodiment of forming a dielectric layer 750 on the passivation layer 600. The dielectric layer 750 may be formed using a deposition process, such as chemical vapor deposition (CVD). Variations of CVD processes suitable for depositing the passivation layer 600 include, but are not limited to, Atmospheric Pressure CVD (APCVD), Low Pressure CVD (LPCVD) and Plasma Enhanced CVD (PECVD), Metal-Organic CVD (MOCVD) and combinations thereof. In another embodiment, the dielectric layer 750 may be formed using a growth process, such as thermal oxidation or nitridation. The dielectric layer 750 is optional, and may be omitted. In another embodiment, the passivation layer 600 may be omitted, and the dielectric layer 750 is deposited in direct contact with the cleaved surface of the bottom cell 100 of the germanium containing material. In this embodiment, the dielectric layer 750 may passivated the cleaved surface of the bottom cell 100.

FIG. 7 depicts one embodiment of forming at least one opening 601 through at least the passivation layer 600 to expose at least a portion of the back surface of the bottom cell 100 of germanium containing material. In the embodiments in which the dielectric layer 750 is present, the at least one opening 601 is also formed through the dielectric layer 750. In one embodiment, forming the at least one opening 601 through the passivation layer 600 and the optional dielectric layer 750 to expose at least a portion of the back surface of the bottom cell 100 of the germanium containing material includes forming a patterned etch mask (not shown) on the passivation layer 600 or the optional dielectric layer 750, and etching exposed portions of the passivation layer 600 and the optional dielectric layer 750 selectively to the patterned etch mask and the back surface of the bottom cell 100 of germanium containing material.

Specifically, and in one example, a patterned etch mask is produced by applying a photoresist to the surface to be etched, exposing the photoresist to a pattern of radiation, and then developing the pattern into the photoresist utilizing a resist developer. Once the patterning of the photoresist is completed, the sections covered by the photoresist are protected, while the exposed regions are removed using a selective etching process that removes the unprotected regions. As used herein, the term “selective” in reference to a material removal process denotes that the rate of material removal for a first material is greater than the rate of removal for at least another material of the structure to which the material removal process is being applied. In some examples, the selectivity may be greater than 100:1, e.g., 1000:1.

In one embodiment, the etch process removes the exposed portions of the passivation layer 600 or the optional dielectric layer 750 with an etch chemistry that is selective to the back surface of the bottom cell 100 comprised of the germanium containing material. In one embodiment, the etch process that forms the openings 601 is an anisotropic etch. An anisotropic etch process is a material removal process in which the etch rate in the direction normal to the surface to be etched is greater than in the direction parallel to the surface to be etched. The anisotropic etch may include reactive-ion etching (RIE). Other examples of anisotropic etching that can be used at this point of the present disclosure include ion beam etching, plasma etching or laser ablation.

FIG. 8 depicts engaging a support substrate assembly to the passivation layer 600, and the optional dielectric layer 750, with an aluminum containing bonding material 800. The support substrate assembly may include an optional transparent conductive material layer 450 that is formed on a support substrate 150. The support substrate assembly that is depicted in FIG. 5, which includes an optional transparent conductive material layer 450 and a support substrate 150, is similar to the support substrate assembly that is described above with reference to FIGS. 1A-4. Therefore, the description of the optional transparent conductive material layer 45 and the support substrate 15 that are depicted in FIG. 4 is suitable for the optional transparent conductive material layer 450 and the support substrate 150 that are depicted in FIG. 5.

In one embodiment, the aluminum-containing bonding material 800 is composed of greater than 90 wt. % aluminum, e.g., greater than 95% aluminum. In another embodiment, the aluminum containing bonding material 800 is composed of greater than 99% aluminum. The aluminum content of the aluminum containing bonding material 800 may be approximately 100% aluminum with incidental impurities. Incidental impurities are impurities that are inadvertently introduced to the aluminum containing bonding material 800 during the processes sequences for forming the aluminum containing bonding material 800. The deposited thickness of the aluminum containing bonding material 800 may range from 5 nm to 40000 nm. In another embodiment, the deposited thickness of the aluminum containing bonding material 800 may range from 10 nm to 20000 nm.

The aluminum containing bonding material 800 may be deposited using a physical vapor deposition (PVD) method, such as sputtering or plating. Examples of sputtering apparatus that may be suitable for depositing the aluminum containing bonding material 800 include DC diode type systems, radio frequency (RF) sputtering, magnetron sputtering, and ionized metal plasma (IMP) sputtering.

In one embodiment, the aluminum containing bonding material 800 is deposited on the passivation layer 600, or the optional dielectric layer 750, and fills the openings 601 through the passivation layer 600, and the optional dielectric layer 750. The aluminum containing bonding material 800 that is deposited of the passivation layer 600, or the optional dielectric layer 750, may then be contacted to the support substrate assembly and thermally annealed, wherein the thermal annealing of the aluminum containing bonding material 800 bonds the passivation layer 600, or the optional dielectric layer 750, to the support substrate assembly. During the thermal annealing/bonding process, aluminum atoms from the aluminum containing bonding material 800 diffuse from the aluminum containing bonding material 800, such as aluminum atoms from the aluminum containing plugs 650, through the cleaved surface of the bottom cell 100 to form the eutectic alloy regions 700 that provide the localized back surface field (BSF) regions.

In some embodiments, instead of a blanket deposition of aluminum containing bonding material 800 across the entire width of the passivation layer 600, or the optional dielectric layer 750, the aluminum containing bonding material 800 may only be deposited to fill the openings 601 that are formed through the passivation layer 600, and the optional dielectric layer 750. In this embodiment, the layer of aluminum containing bonding material 800 that is depicted in FIG. 8 may be omitted.

In some embodiments, in which the passivation layer 600 and the optional dielectric layer 750 is omitted, the aluminum containing bonding material 800 may be locally deposited in direct contact with the cleaved surface C1 of the bottom cell 10 of the germanium containing material. The term “local deposition” denotes that instead of a continuous layer of aluminum containing bonding material 800 that is deposited across the entire width of the photovoltaic device 100B, islands (not shown) of aluminum containing bonding material (also referred to as “aluminum dots”) may be formed in a discontinuous fashion across the width of the photovoltaic device. In this embodiment, the islands of aluminum containing bonding material are used to join the bottom cell 10 to a support substrate assembly, and atoms from the islands of aluminum diffuse into the back surface of the bottom cell 10 to provide localized eutectic alloy regions that function as a localized back surface field (LBSF) region.

In the embodiments, in which the transparent conductive material layer 450 or metal layer are present on the support substrate 150, the transparent conductive material layer 450 is brought into direct contact with the layer of the aluminum containing bonding material 800 (or the aluminum containing plugs 650 when the layer of aluminum containing bonding material 800 is omitted) and is then annealed to form the eutectic alloy regions 700 of aluminum and germanium, and the bond that engages the bottom cell 100 of the germanium containing material to the support substrate assembly that includes the support substrate 150. In the embodiments, in which the transparent conductive material layer 450 is omitted, the support substrate 150 may be brought into direct contact with the aluminum containing bonding material 800 (or the aluminum containing plugs 650 when the layer of aluminum containing bonding material 800 is omitted), and is then annealed.

In another embodiment, the aluminum containing bonding material 800 is deposited directly on the support substrate assembly. For example, in the embodiments in which the support substrate assembly includes an optional transparent conductive material layer 450 that is formed on a support substrate 150, the aluminum containing bonding material 800 may be deposited in direct contact with the optional transparent conductive material layer 450. In another example, in which the optional transparent conductive material layer 450 is omitted, the aluminum containing bonding material 800 may be deposited in direct contact with the support substrate 150. Following the deposition of the aluminum containing bonding material 800 on the support substrate assembly, the aluminum containing bonding material 800 is contacted to the passivation layer 600, or the optional dielectric layer 750, that is present on the cleaved surface of the bottom cell 100 of the germanium containing material.

The structure may then be thermally annealed, in which the aluminum containing bonding material 800 engages the bottom cell 100 to the support substrate assembly, wherein during reflow of the aluminum containing bonding material 800, the aluminum containing bonding material 800 fills the openings 601 through the passivation layer 600, and the optional dielectric layer 750, to provide the aluminum containing plugs 650. During thermal annealing, aluminum atoms from the aluminum containing plugs 650 diffuse into the bottom cell 100 of the germanium containing material to form the eutectic alloy regions 700 of aluminum and germanium.

Thermal annealing of the aluminum containing bonding material 800, and the aluminum containing plugs 650, for each of the above described embodiments may be provided by laser annealing, flash annealing, rapid thermal annealing (RTA) and combinations thereof. The annealing of the aluminum containing bonding material 800, and the aluminum containing plugs 650, is typically conducted at a temperature that is greater than the eutectic temperature for a eutectic alloy of aluminum and germanium. Typically, the eutectic temperature of the eutectic alloy of aluminum and germanium ranges from 400° C. to 500° C. In another embodiment, the eutectic temperature of the eutectic alloy of aluminum and germanium ranges from 425° C. to 475° C. In one example, the eutectic temperature of the eutectic alloy of aluminum and germanium is 426° C. In one embodiment, as the annealing temperature is increased the diffusion of aluminum into the bottom cell 100 of germanium containing material is increased.

Referring to FIG. 5, the front contact 500 may then be formed in electrical communication with at least the at least one top cell 200 of at least one III-V semiconductor material.

While the present disclosure has been particularly shown and described with respect to preferred embodiments thereof, it will be understood by those skilled in the art that the foregoing and other changes in forms and details can be made without departing from the spirit and scope of the present disclosure. It is therefore intended that the present disclosure not be limited to the exact forms and details described and illustrated, but fall within the scope of the appended claims.

What is claimed is:

1. A method of forming a photovoltaic device comprising:
forming at least one top cell comprised of at least one III-V semiconductor material on a bottom cell comprised of a germanium containing material, wherein the germanium containing material may be provided as a substrate having a first thickness;
cleaving the bottom cell comprised of the germanium containing material, wherein a transferred portion of the germanium containing material having a second thickness that is less than the first thickness remains connected to the top cell; and
bonding a support substrate to a cleaved surface of the germanium containing material with a eutectic alloy layer of aluminum and germanium, wherein the eutectic alloy layer of aluminum and germanium passivates the cleaved surface of the germanium containing material.

2. The method of claim 1, wherein the bottom cell that is comprised of the germanium containing material is comprised of crystalline germanium (Ge) and is doped to a p-type conductivity.

3. The method of claim 2, wherein the first thickness of the bottom cell ranges from 500 nm to 50 microns.

4. The method of claim 1, wherein the cleaving of the bottom cell comprised of the germanium containing material comprises mechanical separation, spalling, smart cut layer transfer, epitaxial layer lift-off or a combination thereof.

5. The method of claim 1, wherein the bonding of the support substrate to the cleaved surface of the germanium containing material of the bottom cell with the eutectic alloy layer of aluminum and germanium comprises: applying an aluminum containing metal layer on at least one of the cleaved surface of the germanium containing material of the bottom cell and the support substrate;
contacting the aluminum containing metal layer between the cleaved surface of the germanium containing material and the support substrate; and
annealing at a temperature above a eutectic temperature of the eutectic alloy layer of aluminum and germanium to bond the support substrate to the cleaved surface of the germanium containing material and form a back surface field region that passivates the cleaved surface of the germanium containing material.

6. The method of claim 1, wherein the eutectic alloy layer of aluminum and germanium does not extend across an entire width of a back surface of the bottom cell that is comprised of the germanium containing material, and the back surface field region is a localized back surface filed region, wherein the bonding of the support substrate to the cleaved surface of the germanium containing material of the bottom cell comprises forming aluminum containing dots on at least one of the support substrate, and the cleaved surface of the germanium containing material, contacting the cleaved surface of the germanium containing material to the support substrate in which the aluminum containing dots are present therebetween, and annealing to diffuse aluminum atoms from the aluminum containing dots into the germanium containing material to provide the localized back surface field region.

7. A method of forming a photovoltaic device comprising:
forming at least one top cell comprised of at least one III-V semiconductor material on a bottom cell comprised of a germanium containing material, wherein the germanium containing material may be provided as a substrate having a first thickness;
cleaving the bottom cell comprised of the germanium containing material, wherein a transferred portion of the germanium containing material having a second thickness that is less than the first thickness remains connected to the top cell;
forming a passivation layer comprised of silicon germanium on the back surface of the bottom cell of the germanium-containing material that is opposite the interface between the bottom cell and the at least one top cell;
forming at least one opening is formed through the passivation layer to expose at least a portion of the back surface of the bottom cell of the germanium containing material;
engaging a support substrate to the passivation layer with an aluminum containing bonding material, wherein the aluminum containing bonding material fills the opening through the passivation layer and diffuses into the back surface of the bottom cell of the germanium-containing material to provide a localized back surface field (BSF) region.

8. The method of claim 7, wherein the bottom cell that is comprised of the germanium containing material is comprised of crystalline germanium (Ge) and is in situ doped to a p-type conductivity.

9. The method of claim 7, wherein the cleaving of the bottom cell comprised of the germanium containing material comprises mechanical separation, spalling, smart cut layer transfer, epitaxial lift-off or a combination thereof.

10. The method of claim 7, wherein the forming of the at least one opening through the passivation layer to expose at least a portion of the back surface of the bottom cell of the germanium containing material comprises:
forming a patterned etch mask over the passivation layer; and
etching exposed portions of the passivation layer selectively to the patterned etch mask and the back surface of the bottom cell of the germanium containing material.

11. The method of claim 10, wherein the aluminum containing bonding material is deposited to fill the at least one opening in the passivation layer, and the engaging of the support substrate to the passivation layer comprises contacting the support substrate to the passivation layer and the aluminum bonding material, and annealing to a temperature above the eutectic temperature that is greater than the aluminum germanium eutectic temperature to forming the localized back surface field (BSF) region.
